(19) United States
(12) Patent Application Publication
(10) Pub. No.: US 2025/0344315 A1
(43) Pub. Date: Nov. 6, 2025

(54) THERMAL BRIDGE FOR AN ELECTRICAL COMPONENT

(71) Applicant: TE Connectivity Solutions GmbH, Schaffhausen (CH)

(72) Inventor: Alan Weir Bucher, Middletown, PA (US)

(21) Appl. No.: 18/651,808

(22) Filed: May 1, 2024

(51) Int. Cl. H05K 1/02

(52) U.S. Cl. CPC H05K 1/0207; H05K 2201/066

(57) ABSTRACT

A thermal bridge for thermally coupling an electrical component and a heat transfer device to dissipate heat from the electrical component to the heat transfer device includes upper and lower bridge assemblies includes upper and lower transfer plates, respectively. The transfer plates have sides configured to interface to thermally transfer heat from the lower bridge assembly to the upper bridge assembly. Upper ends of the upper transfer plates face and thermally couple to the heat transfer device. Lower ends of the lower transfer plates face and thermally couple to the electrical component. Upper ends of the lower transfer plates face the heat transfer device. A spring element positioned between the bridge assemblies bias against the transfer plates with an opening force.

### BACKGROUND OF THE INVENTION

The subject matter herein relates generally to heat dissipation for electrical components.

It may be desirable to transfer thermal energy (or heat) away from designated components of a system or device. Some systems use electrical components, such as electrical connectors, to transmit data and/or electrical power to and from different systems or devices. Some systems use electrical components, such as pluggable modules for transmitting data signals through communication cable(s) in the form of optical signals and/or electrical signals. Some systems use electrical components, such as integrated circuits, for controlling the system. The electrical components define heat generating sources within the system.

A common challenge that confronts developers of electrical systems is heat management. Thermal energy generated by electrical components within a system can degrade performance or even damage components of the system. To dissipate the thermal energy, systems include a thermal component, such as a heat sink, which engages the heat source, absorbs the thermal energy from the heat source, and transfers the thermal energy away. The heat sink is typically thermally coupled to another thermal component at yet another thermal interface. The components lose efficiency at each thermal interface. Additionally, it is difficult to achieve efficient thermal coupling at the interfaces due to limited thermal interface areas and variations in the surfaces, such as due to surface flatness of the interfacing surfaces. Moreover, the thermal transfer devices are typically relatively tall, increasing the overall height of the system. It is desirable to decrease the overall height of the components.

There is a need for a thermal transfer assembly that efficiently transfers thermal energy away from an electrical component.

### BRIEF DESCRIPTION OF THE INVENTION

In one embodiment, a thermal bridge for thermally coupling an electrical component and a heat transfer device to transport heat from the electrical component to the heat transfer device is provided. The thermal bridge includes an upper bridge assembly which includes a plurality of upper transfer plates. Each upper transfer plate has a front end and a rear end. Each upper transfer plate has sides between the front end and the rear end. Each upper transfer plate has an upper end and a lower end. The upper ends of the upper transfer plates configured to face and thermally couple to the heat transfer device. The thermal bridge includes a lower bridge assembly which includes a plurality of lower transfer plates. Each lower transfer plate has a front end and a rear end. Each lower transfer plate has sides between the front end and the rear end. The sides of the lower transfer plates are configured to interface with the sides of the upper transfer plates to thermally transfer heat from the lower bridge assembly to the upper bridge assembly. Each lower transfer plate has an upper end and a lower end. The lower ends of the lower transfer plates configured to face and thermally couple to the electrical component. The upper ends of the lower transfer plates configured to face the heat transfer device without obstruction. The thermal bridge includes a spring element positioned between the upper bridge assembly and the lower bridge assembly. The spring element includes an upper spring member engaging the upper transfer plates to bias the upper transfer plates with an opening force generally away from the lower transfer plates. The spring element includes a lower spring member engaging the lower transfer plates to bias the lower transfer plates with an opening force generally away from the upper transfer plates.

In another embodiment, a thermal bridge for thermally coupling an electrical component and a heat transfer device to transport heat from the electrical component to the heat transfer device is provided. The thermal bridge includes an upper bridge assembly which includes a plurality of upper transfer plates. Each upper transfer plate has a front end and a rear end. Each upper transfer plate has sides between the front end and the rear end. Each upper transfer plate has an upper end and a lower end. The upper ends of the upper transfer plates configured to face and thermally couple to the heat transfer device. The thermal bridge includes a lower bridge assembly which includes a plurality of lower plates arranged in a lower plate stack. The lower plates include lower transfer plates and lower spacer plates between the lower transfer plates. Each lower transfer plate has a front end and a rear end. Each lower transfer plate has sides between the front end and the rear end. The sides of the lower transfer plates are configured to interface with the sides of the upper transfer plates to thermally transfer heat from the lower bridge assembly to the upper bridge assembly. Each lower transfer plate has an upper end and a lower end. The lower ends of the lower transfer plates are configured to face and thermally couple to the electrical component. The upper ends of the lower transfer plates are configured to face the heat transfer device without obstruction. Each lower spacer plate has a front end and a rear end. Each lower spacer plate has sides between the front end and the rear end. Each lower spacer plate has an upper end and a lower end. The lower ends of the lower spacer plates are configured to face and thermally couple to the electrical component. The upper ends of the lower spacer plates facing the lower ends of the upper transfer plates. The thermal bridge includes a spring element positioned between the upper bridge assembly and the lower bridge assembly. The spring element includes an upper spring member engaging the upper transfer plates to bias the upper transfer plates with an opening force generally away from the lower transfer plates. The spring element includes a lower spring member engaging the lower transfer plates to bias the lower transfer plates with an opening force generally away from the upper transfer plates.

In a further embodiment, a thermal bridge for thermally coupling an electrical component and a heat transfer device to transport heat from the electrical component to the heat transfer device is provided. The thermal bridge includes an upper bridge assembly which includes a plurality of upper transfer plates. Each upper transfer plate has a front end and a rear end. Each upper transfer plate has sides between the front end and the rear end. Each upper transfer plate has an upper end and a lower end. The upper ends of the upper transfer plates are configured to face and thermally couple to the heat transfer device. The thermal bridge includes a lower bridge assembly which includes a plurality of lower transfer plates. Each lower transfer plate has a front end and a rear end. Each lower transfer plate has sides between the front end and the rear end. Each lower transfer plate has an upper end and a lower end. The lower ends of the lower transfer plates are configured to face and thermally couple to the electrical component. The thermal bridge includes a spring element positioned between the upper bridge assembly and the lower bridge assembly. The spring element includes an upper spring member engaging the upper transfer plates to bias the upper transfer plates with an opening force generally away from the lower transfer plates. The spring element includes a lower spring member engaging the lower transfer plates to bias the lower transfer plates with an opening force generally away from the upper transfer plates. The sides of the lower transfer plates interface with the sides of the upper transfer plates to thermally transfer heat from the lower bridge assembly to the upper bridge assembly. The upper bridge assembly includes upper gaps between the upper transfer plates at the upper ends of the upper transfer plates and the lower bridge assembly includes lower gaps between the lower transfer plates at the lower ends of the lower transfer plates. The lower ends of the upper transfer plates are configured to face the electrical component through the lower gaps. The upper ends of the lower transfer plates are configured to face the heat transfer device through the upper gaps.

### BRIEF DESCRIPTION OF THE DRAWINGS

FIG. 1 is a front perspective view of a communication system and a thermal bridge in accordance with an exemplary embodiment for dissipating heat from at least one electrical component of the communication system.

FIG. 2 is a sectional view of the thermal bridge in accordance with an exemplary embodiment.

FIG. 3 is an enlarged cross-sectional view of a portion of the thermal bridge in accordance with an exemplary embodiment.

FIG. 4 is a cross-sectional view of the thermal bridge in accordance with an exemplary embodiment.

FIG. 5 is a cross-sectional view of the thermal bridge in accordance with an exemplary embodiment.

FIG. 6 is an enlarged cross-sectional view of a portion of the thermal bridge in accordance with an exemplary embodiment.

### DETAILED DESCRIPTION OF THE INVENTION

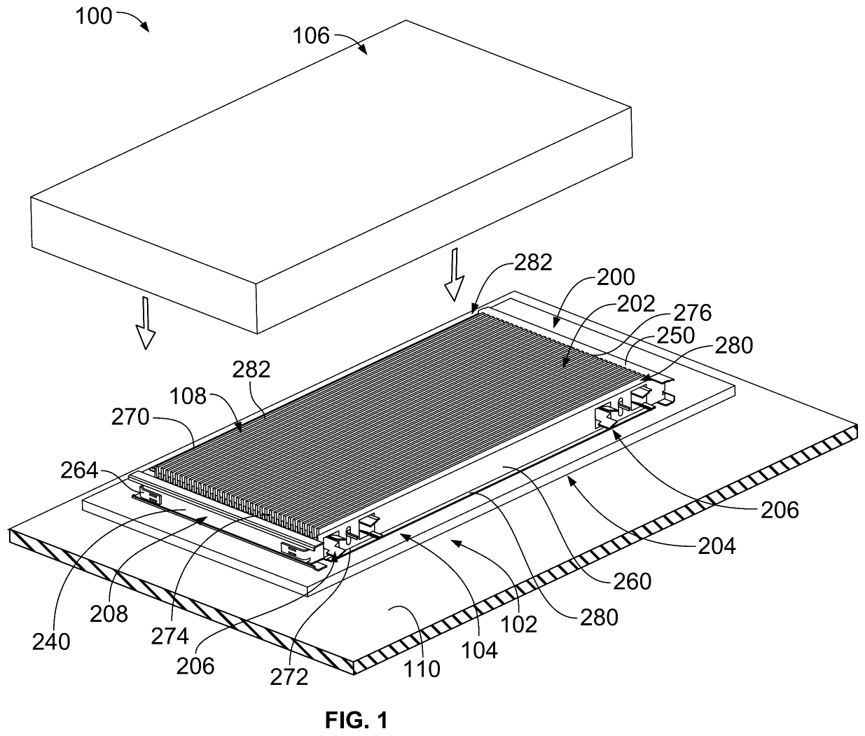

FIG. 1 is a front perspective view of a communication system 100 and a thermal bridge 200 in accordance with an exemplary embodiment for dissipating heat from at least one electrical component 102 of the communication system 100. The thermal bridge 200 is configured to be thermally coupled to the electrical component 102 at a lower thermal interface 104 at a bottom of the thermal bridge 200. In an exemplary embodiment, a heat transfer device 106 is provided to dissipate heat from the thermal bridge 200. For example, the thermal bridge 200 is configured to be thermally coupled to the heat transfer device 106 at an upper thermal interface 108. The thermal bridge 200 thermally connects the electrical component 102 and the heat transfer device 106 to transport heat from the electrical component 102. The heat transfer device 106 may be a heat sink, such as a finned heat sink, configured to be air cooled by transferring heat to the passing airflow. In other various embodiments, the heat transfer device 106 may be a heat spreader, a cold plate having liquid cooling, and the like.

In an exemplary embodiment, the thermal bridge 200 is compressible between the electrical component 102 and the heat transfer device 106. In an exemplary embodiment, the lower thermal interface 104 is conformable to a shape of the electrical component 102 and the upper thermal interface 108 is conformable to a shape of the heat transfer device 106 for efficient thermal transfer therebetween. For example, the thermal bridge 200 may be a stacked plate-like structure wherein the individual plates are movable relative to each other to conform to the electrical component 102 and the heat transfer device 106. Thermal grease or other thermal interface materials may be provided at the interface(s) such as at the upper thermal interface 108 to enhance thermal transfer between the thermal bridge and the other component(s).

In an exemplary embodiment, the electrical component 102 is mounted to a circuit board 110. In various embodiments, the electrical component 102 may be a communication connector, such as a receptacle connector, a header connector, a plug connector, or another type of communication connector. In other various embodiments, the electrical component 102 may be an electronic package, such as an integrated circuit. In other various embodiments, the electrical component 102 may be a pluggable module, such as an I/O transceiver module. Other types of electrical components may be provided in alternative embodiments.

In an exemplary embodiment, the thermal bridge 200 includes an upper bridge assembly 202, a lower bridge assembly 204, a spring element 206 between the upper and lower bridge assemblies 202, 204, and a bridge frame 208 for holding the upper and lower bridge assemblies 202, 204 together. The lower bridge assembly 204 is configured to thermally engage the electrical component 102. The upper bridge assembly 202 is configured to transfer heat to the heat transfer device 106. The upper bridge assembly 202 is in thermal communication with the lower bridge assembly 204 and transfers heat away from the lower bridge assembly 204 to cool the electrical component 102.

The spring element(s) 206 biases the upper and lower bridge assemblies 202, 204 apart. The upper and lower bridge assemblies 202, 204 are compressible relative to each other. For example, the upper and lower bridge assemblies 202, 204 are compressible between the electrical component 102 and the heat transfer device 106 (for example, compress the spring element 206).

The bridge frame 208 provides support for the upper and lower bridge assemblies 202, 204. For example, the bridge frame 208 may surround the outer perimeter or periphery of the thermal bridge 200 to hold the components in an interior space of the bridge frame 208. In an exemplary embodiment, the bridge frame 208 may extend along the sides and ends, leaving the top and bottom to form thermal interfaces with the electrical component 102 and the heat transfer device 106. Optionally, the bridge frame 208 may provide internal support through the bridge assemblies 202, 204. For example, connecting spars, pins, or other types of internal connecting elements may pass through the bridge assemblies 202, 204.

In an exemplary embodiment, the spring element 206 presses the upper bridge assembly 202 outward in a first biasing direction (for example, upward) against the bridge frame 208 and the spring element 206 presses the lower bridge assembly 204 outward in a second biasing direction (for example, downward) against the bridge frame 208. The upper bridge assembly 202 and the lower bridge assembly 204 may be held by the bridge frame 208 in a manner to allow a limited amount of floating movement of the upper bridge assembly 202 and the lower bridge assembly 204 relative to the bridge frame 208.

In an exemplary embodiment, the thermal bridge 200 is parallelepiped (for example, generally box shaped). For example, the thermal bridge 200 includes a top 270, a bottom 272, a front 274, a rear 276, a first side 280, and a second side 282. The top 270 may be generally planar. The bottom 272 may be generally planar. The front 274 may be generally planar. The rear 276 may be generally planar. The first side 280 may be generally planar. The second side 282 may be generally planar. However, the thermal bridge 200 may have other shapes in alternative embodiments. The frame structure used to hold the thermal bridge 200 together is defined by the bridge frame 208. The top 270 and the bottom 272 have large surface areas to allows for a large amount of usable external surface area for heat transfer.

In an exemplary embodiment, the bridge assemblies 202, 204 each include a plurality of plates that are arranged together in plate stacks. The plates are interleaved with each other for thermal communication between the upper bridge assembly 202 and the lower bridge assembly 204. The individual plates are movable relative to each other such that the plates may be individually articulated to conform to the electrical component 102 and/or the heat transfer device 106. For example, the individual plates may conform to the electrical component 102 at the lower thermal interface 104 for improved contact and/or proximity between the thermal bridge 200 and the electrical component 102 and/or the individual plates may conform to the heat transfer device 106 at the upper thermal interface 108 for improved contact and/or proximity between the thermal bridge 200 and the heat transfer device 106. A gap or space may be provided between the plates of the upper and lower bridge assemblies 202, 204 to allow compressive movement of the spring element 206 between the bridge assemblies 202, 204.

In an exemplary embodiment, the bridge frame 208 is manufactured from a plurality of frame elements, which may be connected together to form a supporting structure for the bridge assemblies 202, 204. For example, the frame elements may surround the outer perimeter of the plate stacks. The frame elements may pass through the interior of the plate stacks to hold the bridge assemblies 202, 204. In an exemplary embodiment, the bridge frame 208 includes a front rail 240, a rear rail 250, a first side rail 260 extending between the front and rear rails 240, 250, and a second side rail 270 extending between the front and rear rails 240, 250. The rails may be stamped and formed elements. In an exemplary embodiment, front and rear rails 240, 250 engage the bridge assemblies 202, 204 to limit spreading apart of the bridge assemblies 202, 204 against the opening forces of the spring element 206.

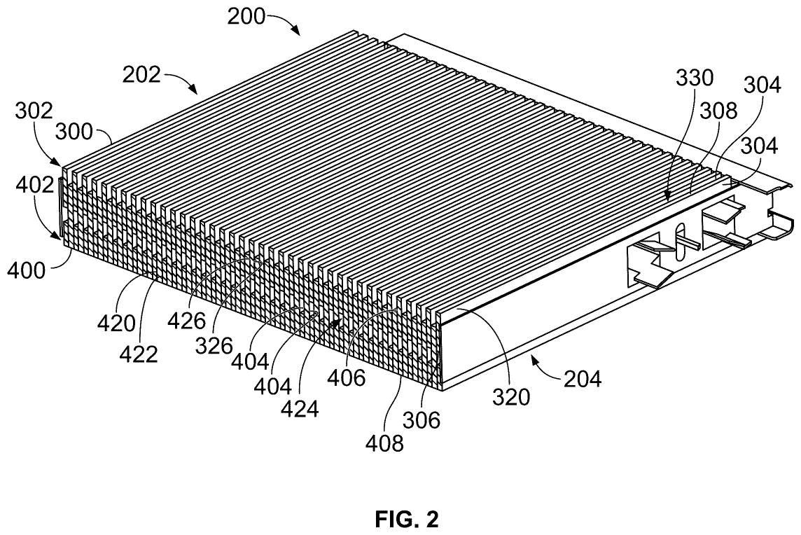

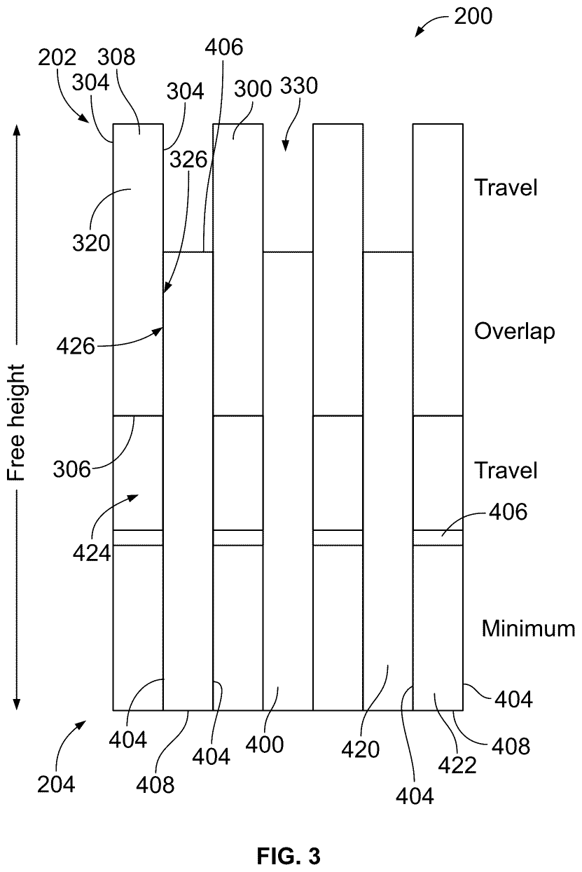

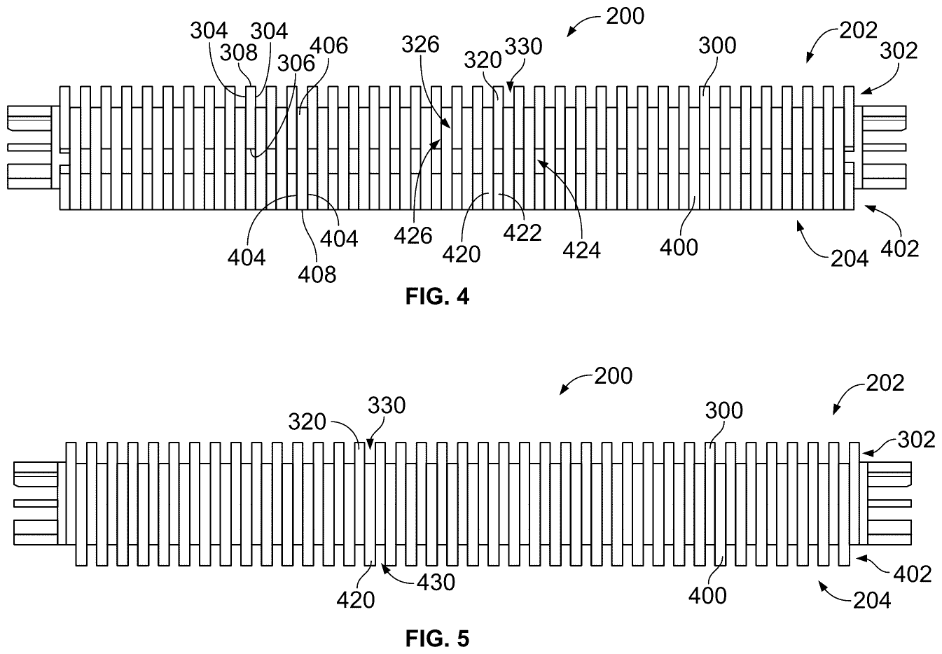

FIG. 2 is a cross-sectional view of the thermal bridge 200 in accordance with an exemplary embodiment. FIG. 3 is an enlarged cross-sectional view of a portion of the thermal bridge 200 in accordance with an exemplary embodiment. FIG. 4 is a cross-sectional view of the thermal bridge 200 in accordance with an exemplary embodiment. The thermal bridge 200 includes the upper bridge assembly 202 and the lower bridge assembly 204. In an exemplary embodiment, the upper bridge assembly 202 includes a plurality of upper plates 300 arranged in an upper plate stack 302. In an exemplary embodiment, the lower bridge assembly 204 includes a plurality of lower plates 400 arranged in a lower plate stack 402. The upper plates 300 are interleaved with the lower plates 400 in the plate stacks 302, 402.

Each upper plate 300 has sides 304 extending between a lower end 306 and an upper end 308 of the upper plate 300. The lower end 306 faces the lower bridge assembly 204. The upper end 308 faces outward, such as toward the heat transfer device 106. For example, there is no other component between the upper end 308 and the heat transfer device 106. However, there may be a thermal interface material or thermal grease at the upper end 308 to enhance heat transfer to the heat transfer device 106. In an exemplary embodiment, all of the upper plates 300 have the same shape, such as the same height/thickness/length. In alternative embodiments, various upper plates 300 may have different shapes, such as different heights and/or different features between the lower end 306 and the upper end 308.

In an exemplary embodiment, the upper plates 300 include upper transfer plates 320 and upper gaps 330 between the upper transfer plates 320. The upper gaps 330 are located above corresponding lower plates 400. The upper gaps 330 extend to the upper ends 306 of the upper transfer plates 320. For example, the upper gaps 330 are open at the upper thermal interface 108. The upper gaps 330 expose the upper transfer plates 320 to air or other fluid (for example, thermal grease) between the upper transfer plates 320. In an exemplary embodiment, the upper plates 300 do not include any spacer plates between the upper transfer plates 320. Rather, spacer plates are eliminated, leaving the upper gaps 330. Elimination of any upper spacers (for example, included in conventional thermal bridges) reduces the overall height of the thermal bridge 200. For example, the upper transfer plates 320 may be made shorter. The upper transfer plates 320 may be transferred downward toward the lower plates 400 to reduce the overall height of the thermal bridge 200. Elimination of the upper spacer plates may increase the amount of travel of the upper plates 300 and/or the lower plates 400 within the thermal bridge 200, such as to accommodate a greater positional tolerance between the electrical component 102 and the heat transfer device 106. Elimination of the upper spacer plates may increase the amount of overlap of the upper and lower plates 300, 400 to improve thermal transfer between the upper and lower plates 300, 400. The upper ends 308 of the upper transfer plates 320 define the upper thermal interface 108. In the illustrated embodiment, the upper thermal interface 108 is discontinuous with the upper gaps 330 forming discontinuities along the upper thermal interface 108. Thermal grease (not shown) along the upper ends 308 may enhance heat transfer at the upper thermal interface 108. The thermal grease may at least partially fill the upper gaps 330.

Each lower plate 400 has sides 404 extending between an upper end 406 and a lower end 408 of the lower plate 400. The upper end 406 faces upward. Optionally, at least some of the upper ends 406 may face the heat transfer device 106. For example, the upper ends 406 may face the heat transfer device 106 without obstruction, such as from another plate. The upper ends 406 may face the heat transfer device 106 through the gaps between the upper plates 300. There is no other component between such upper ends 406 and the heat transfer device 106. In various embodiments, the upper ends 406 may interface with the heat transfer device 106, such as when the thermal bridge 200 is compressed. Optionally, some of the lower plates 400 may face the upper plates 300. For example, the upper ends 406 of such plates may face the lower ends of the upper plates 300 of the upper bridge assembly 202. The lower ends 408 of the lower plates 400 face outward, such as toward the electrical component 102 (shown in FIG. 1). For example, there is no other component between the lower ends 408 and the electrical component 102. Optionally, various lower plates 400 may have different shapes and/or heights between the upper end 406 and the lower end 408. In alternative embodiments, all of the lower plates 400 may have the same shape, such as the same height/thickness/length.

In an exemplary embodiment, the lower plates 400 include lower transfer plates 420 and lower spacer plates 422. The lower spacer plates 422 are located between the lower transfer plates 420. The lower transfer plates 420 are configured to overlap with the upper transfer plates 320 to thermally couple the lower bridge assembly 204 and the upper bridge assembly 202.

The lower spacer plates 422 are aligned with upper transfer plates 320. The upper ends 406 of the lower spacer plates 422 face the lower ends 308 of the upper transfer plates 320. For example, there is no other component between the upper end 406 and the upper transfer plate 320. There may be a gap, such as an air gap, between the upper end 406 of the lower spacer plate 422 and the lower end 308 of the upper transfer plate 320. The upper ends 406 of the lower spacer plates 422 may abut against the lower ends 308 of the upper transfer plates 320 when the thermal bridge 200 is compressed, such as to define a compression limit for the thermal bridge 200. In an exemplary embodiment, travel gaps 424 are defined between the lower spacer plates 422 and the upper transfer plates 320. The travel gaps 424 provide spaces for travel of the lower spacer plates 422 and/or the upper transfer plates 320 to allow compression of the thermal bridge 200. In an exemplary embodiment, the lower spacer plates 422 are shorter than the lower transfer plates 420. In an exemplary embodiment, the lower spacer plates 422 may have a minimum height within the thermal bridge 200. The minimum height may be limited by manufacturing processes, such as stamping processes. The lower spacer plates 422 are a minimum height to reduce the overall height of the thermal bridge 200, such as to allow increased size of the travel gaps 424 and/or to allow increased height of the upper transfer plate 320 to allow increased overlap and thermal transfer with the lower transfer plates 420.

The lower transfer plates 420 are aligned with the upper gaps 330. The lower transfer plates 420 are configured to face the heat transfer device 106. For example, the upper ends 406 of the lower transfer plates 420 face the heat transfer device 106 without obstruction through the upper gaps 330. For example, there are no upper plates 300 between the lower transfer plates 420 and the heat transfer device 106. The upper bridge assembly 202 is devoid of spacer plates between the upper transfer plates 320, rather leaving the upper gaps 330 open, which allows the thermal bridge 200 to have a lower height or profile and/or to allow taller lower transfer plates 420 to increase thermal overlap between the plates and/or to allow a greater range of travel/compression. In the illustrated embodiment, there is no other component between the upper end 406 and the heat transfer device 106. Rather, the upper gaps 330 are open between the upper transfer plates 420 allowing the upper ends 406 of the lower transfer plates 420 to face the heat transfer device 106. In various embodiments, the upper ends 406 of the lower transfer plates 420 may interface with the heat transfer device 106, such as when the thermal bridge 200 is compressed, such as to operate as a compression limit or compression stop. The lower transfer plates 420 are configured to move into the upper gaps 330 during compression of the thermal bridge 200. The lower transfer plates 420 are spaced apart from each other and held at spaced locations by the upper transfer plates 320. For example, the upper ends 406 are held at the spaced locations in the plate stack by the upper transfer plates 320. Similarly, the lower transfer plates 420 hold the upper transfer plates 320 at spaced apart positions relative to each other. For example, the lower ends 306 of the upper transfer plates 320 are held at the spaced locations in the plate stack by the lower transfer plates 420.

In an exemplary embodiment, the upper transfer plates 320 include upper overlapping regions 326 and the lower transfer plates 420 include lower overlapping regions 426. The upper bridge assembly 202 and the lower bridge assembly 204 are internested such that the upper overlapping regions 326 thermally interface with the lower overlapping regions 426 to thermally couple the upper transfer plates 320 and the lower transfer plates 420. The amount of overlap of the overlapping regions 326, 426 increases as the thermal bridge 200 is compressed. As such, the amount of thermal transfer between the upper bridge assembly 202 and the lower bridge assembly 204 increases as the thermal bridge 200 is compressed.

The lower ends 408 of the lower transfer plates 420 and the lower ends 408 of the lower spacer plates 422 form the lower thermal interface 104. The lower ends 408 of the lower transfer plates 420 and the lower ends 408 of the lower spacer plates 422 are configured to face and engage the electrical component 102. The lower plates 400 are discrete from each other to allow movement relative to each other within the lower plate stack. As such, the lower ends 408 of the lower transfer plates 420 and the lower ends 408 of the lower spacer plates 422 are configured to conform to the electrical component 102 for efficient thermal transfer from the electrical component 102 to the thermal bridge 200.

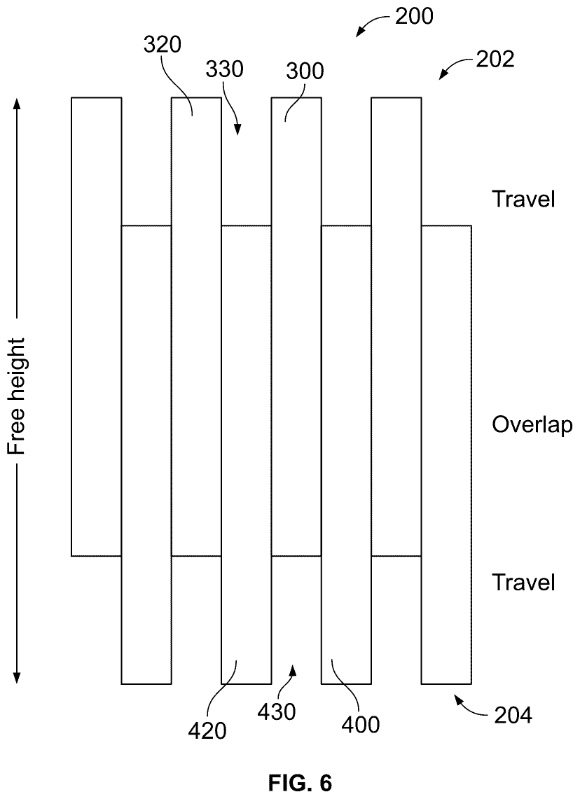

FIG. 5 is a cross-sectional view of the thermal bridge 200 in accordance with an exemplary embodiment. FIG. 6 is an enlarged cross-sectional view of a portion of the thermal bridge 200 in accordance with an exemplary embodiment. The thermal bridge 200 includes the upper bridge assembly 202 and the lower bridge assembly 204. The upper bridge assembly 202 includes a plurality of the upper plates 300 arranged in an upper plate stack 302 and the lower bridge assembly 204 includes a plurality of the lower plates 400 arranged in a lower plate stack 402. The upper plates 300 are interleaved with the lower plates 400 in the plate stacks 302, 402. In the illustrated embodiment, the lower bridge assembly 204 is similar to the lower bridge assembly shown in FIGS. 2-4; however, the lower bridge assembly 204 shown in FIGS. 5-6 do not include any of the lower spacer plates 422. Rather, the lower bridge assembly 204 includes lower gaps 430 between the lower transfer plates 420, similar to the upper gaps 330 between the upper transfer plates 320.

The lower gaps 430 are located below the corresponding upper transfer plates 320. The lower gaps 430 extend to the lower ends 408 of the lower transfer plates 420. For example, the lower gaps 430 are open at the lower thermal interface 104. The lower gaps 430 expose the lower transfer plates 420 to air or other fluid (for example, thermal grease) between the lower transfer plates 420. In an exemplary embodiment, the lower plates 400 do not include any spacer plates between the lower transfer plates 420. Rather, the spacer plates 422 (shown in FIGS. 2-4) are eliminated, leaving the lower gaps 430. Elimination of any lower spacers reduces the overall height of the thermal bridge 200. For example, the lower transfer plates 420 may be made shorter. The upper transfer plates 320 may be transferred downward toward the lower ends 408 of the lower transfer plates 420 to reduce the overall height of the thermal bridge 200. Elimination of the lower spacer plates may increase the amount of travel of the lower transfer plates 420 and/or the upper transfer plates 320 within the thermal bridge 200, such as to accommodate a greater positional tolerance between the electrical component 102 and the heat transfer device 106. Elimination of the lower spacer plates may increase the amount of overlap of the upper and lower transfer plates 320, 420 to improve thermal transfer between the upper and lower transfer plates 320, 420.

The lower ends 408 of the lower transfer plates 420 define the lower thermal interface 104. In the illustrated embodiment, the lower thermal interface 104 is discontinuous with the lower gaps 430 forming discontinuities along the lower thermal interface 104. Thermal grease (not shown) along the lower ends 408 may enhance heat transfer at the lower thermal interface 108. The thermal grease may at least partially fill the lower gaps 430.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112(f), unless and until such claim limitations expressly use the phrase “means for” followed by a statement of function void of further structure.

What is claimed is:

1. A thermal bridge for thermally coupling an electrical component and a heat transfer device to dissipate heat from the electrical component to the heat transfer device, the thermal bridge comprising:
an upper bridge assembly including a plurality of upper transfer plates, each upper transfer plate having a front end and a rear end, each upper transfer plate having sides between the front end and the rear end, each upper transfer plate having an upper end and a lower end, the upper ends of the upper transfer plates configured to face and thermally couple to the heat transfer device;
a lower bridge assembly including a plurality of lower transfer plates, each lower transfer plate having a front end and a rear end, each lower transfer plate having sides between the front end and the rear end, the sides of the lower transfer plates configured to interface the sides of the upper transfer plates to thermally transfer heat from the lower bridge assembly to the upper bridge assembly, each lower transfer plate having an upper end and a lower end, the lower ends of the lower transfer plates configured to face and thermally couple to the electrical component, the upper ends of the lower transfer plates configured to face the heat transfer device without obstruction; and
a spring element positioned between the upper bridge assembly and the lower bridge assembly, the spring element including an upper spring member engaging the upper transfer plates to bias the upper transfer plates with an opening force generally away from the lower transfer plates, the spring element including a lower spring member engaging the lower transfer plates to bias the lower transfer plates with an opening force generally away from the upper transfer plates.

2. The thermal bridge of claim 1, wherein the upper bridge assembly includes upper gaps between the upper transfer plates at the upper ends of the upper transfer plates, the upper ends of the lower transfer plates configured to face the heat transfer device through the upper gaps.

3. The thermal bridge of claim 2, wherein the lower bridge assembly includes lower gaps between the lower transfer plates at the lower ends of the lower transfer plates, the lower ends of the upper transfer plates configured to face the electrical component through the lower gaps.

4. The thermal bridge of claim 2, wherein the upper gaps are at least partially filled with thermal grease.

5. The thermal bridge of claim 1, wherein the upper transfer plates are spaced apart from each other and held at spaced locations by the lower transfer plates.

6. The thermal bridge of claim 1, wherein the upper bridge assembly includes an upper thermal interface defined by the upper ends of the upper transfer plates, the upper thermal interface configured to be thermally coupled to the heat transfer device, the upper thermal interface being discontinuous.

7. The thermal bridge of claim 1, wherein the lower bridge assembly includes lower spacer plates positioned between the lower transfer plates, the lower spacer plates being aligned with the upper transfer plates between the lower transfer plates.

8. The thermal bridge of claim 1, wherein the spring element is compressible allowing the upper transfer plates to move relative to the lower transfer plates to move the upper ends of the upper transfer plates closer to the upper ends of the lower transfer plates.

9. The thermal bridge of claim 1, wherein the upper transfer plates are held in an upper plate stack without spacer plates therebetween.

10. The thermal bridge of claim 1, wherein all of the upper plates in the upper bridge assembly have a same height.

11. The thermal bridge of claim 10, wherein all of the lower plates in the lower bridge assembly have a same height.

12. The thermal bridge of claim 1, further comprising a bridge frame holding the upper bridge assembly and the lower bridge assembly.

13. The thermal bridge of claim 1, wherein the upper transfer plates and the lower transfer plates are movable relative to each other to conform the upper transfer plates to the heat transfer device and to conform the lower transfer plates to the electrical component.

14. The thermal bridge of claim 1, wherein the upper transfer plates include upper overlapping regions and the lower transfer plates include lower overlapping regions, the upper bridge assembly and the lower bridge assembly being internested such that the upper overlapping regions thermally interface with the lower overlapping regions to thermally couple the upper transfer plates and the lower transfer plates.

15. A thermal bridge for thermally coupling an electrical component and a heat transfer device to dissipate heat from the electrical component to the heat transfer device, the thermal bridge comprising:
an upper bridge assembly including a plurality of upper transfer plates, each upper transfer plate having a front end and a rear end, each upper transfer plate having sides between the front end and the rear end, each upper transfer plate having an upper end and a lower end, the upper ends of the upper transfer plates configured to face and thermally couple to the heat transfer device;
a lower bridge assembly including a plurality of lower plates arranged in a lower plate stack, the lower plates including lower transfer plates and lower spacer plates between the lower transfer plates, each lower transfer plate having a front end and a rear end, each lower transfer plate having sides between the front end and the rear end, the sides of the lower transfer plates configured to interface with the sides of the upper transfer plates to thermally transfer heat from the lower bridge assembly to the upper bridge assembly, each lower transfer plate having an upper end and a lower end, the lower ends of the lower transfer plates configured to face and thermally couple to the electrical component, the upper ends of the lower transfer plates configured to face the heat transfer device without obstruction, each lower spacer plate having a front end and a rear end, each lower spacer plate having sides between the front end and the rear end, each lower spacer plate having an upper end and a lower end, the lower ends of the lower spacer plates configured to face and thermally couple to the electrical component, the upper ends of the lower spacer plates facing the lower ends of the upper transfer plates; and
a spring element positioned between the upper bridge assembly and the lower bridge assembly, the spring element including an upper spring member engaging the upper transfer plates to bias the upper transfer plates with an opening force generally away from the lower transfer plates, the spring element including a lower spring member engaging the lower transfer plates to bias the lower transfer plates with an opening force generally away from the upper transfer plates.

16. The thermal bridge of claim 15, wherein the upper bridge assembly includes upper gaps between the upper transfer plates at the upper ends of the upper transfer plates, the lower transfer plates aligned with the upper gaps, the upper ends of the lower transfer plates configured to face the heat transfer device through the upper gaps.

17. The thermal bridge of claim 15, wherein all of the upper plates in the upper bridge assembly have a same height.

18. A thermal bridge for thermally coupling an electrical component and a heat transfer device to dissipate heat from the electrical component to the heat transfer device, the thermal bridge comprising:
an upper bridge assembly including a plurality of upper transfer plates, each upper transfer plate having a front end and a rear end, each upper transfer plate having sides between the front end and the rear end, each upper transfer plate having an upper end and a lower end, the upper ends of the upper transfer plates configured to face and thermally couple to the heat transfer device;
a lower bridge assembly including a plurality of lower transfer plates, each lower transfer plate having a front end and a rear end, each lower transfer plate having sides between the front end and the rear end, each lower transfer plate having an upper end and a lower end, the lower ends of the lower transfer plates configured to face and thermally couple to the electrical component; and
a spring element positioned between the upper bridge assembly and the lower bridge assembly, the spring element including an upper spring member engaging the upper transfer plates to bias the upper transfer plates with an opening force generally away from the lower transfer plates, the spring element including a lower spring member engaging the lower transfer plates to bias the lower transfer plates with an opening force generally away from the upper transfer plates;
wherein the sides of the lower transfer plates interface the sides of the upper transfer plates to thermally transfer heat from the lower bridge assembly to the upper bridge assembly; and
wherein the upper bridge assembly includes upper gaps between the upper transfer plates at the upper ends of the upper transfer plates and the lower bridge assembly includes lower gaps between the lower transfer plates at the lower ends of the lower transfer plates, the lower ends of the upper transfer plates configured to face the electrical component through the lower gaps, the upper ends of the lower transfer plates configured to face the heat transfer device through the upper gaps.

19. The thermal bridge of claim 18, wherein the upper transfer plates are held in an upper plate stack without spacer plates therebetween, and wherein the lower transfer plates are held in a lower plate stack without spacer plates therebetween.

20. The thermal bridge of claim 18, wherein all of the upper plates in the upper bridge assembly have a same height and wherein all of the lower plates in the lower bridge assembly have a same height.
